(19) United States
(12) Patent Application Publication
(10) Pub. No.: US 2026/0293285 A1
(43) Pub. Date: Sep. 24, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Kentaro ICHINOSEKI, Higashimurayama Tokyo (JP); Tatsuya NISHIWAKI, Yokohama Kanagawa (JP); Hiroki SAKATA, Kawasaki Kanagawa (JP); Kohei OASA, Chuo Tokyo (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/300,754

(22) Filed: Aug. 15, 2025

(30) Foreign Application Priority Data
Mar. 21, 2025 (JP) 2025-047421
May 30, 2025 (JP) 2025-090563

(51) Int. Cl. H10D 84/00; H10D 62/832; H10D 64/00; H10D 64/23; H10D 84/01

(52) U.S. Cl. CPC H10D 84/146; H10D 62/8325; H10D 64/117; H10D 64/2527; H10D 84/0109

(57) ABSTRACT

A semiconductor part located on the first electrode, a conductive metal-oxide film, a second electrode, an insulating member, and a third electrode located inside the insulating member. The semiconductor part is of a first conductivity type. A first trench and a second trench are formed in an upper surface of the semiconductor part. The first trench and the second trench are separated from each other. The conductive metal-oxide film is located on at least a side surface of the first trench. The conductive metal-oxide film contacts the semiconductor part. The second electrode is located inside the first trench and on the semiconductor part. The second electrode contacts the conductive metal-oxide film and including a metal. The insulating member is located inside the second trench.

### CROSS-REFERENCE TO RELATED APPLICATIONS

This application is based upon and claims the benefit of priority from Japanese Patent Application No.2025-047421, filed on Mar. 21, 2025, and Japanese Patent Application No.2025-090563, filed on May 30, 2025; the entire contents of which are incorporated herein by reference.

### FIELD

Embodiments described herein relate generally to a semiconductor device.

### BACKGROUND

In recent years, semiconductor devices are being developed in which a transistor part formed of a semiconductor and a diode part formed of a Schottky junction are realized by embedding a metal member inside a source trench. In such a semiconductor device, it is desirable to set the threshold of the transistor part to a prescribed value while maintaining a low resistance of the diode part.

### BRIEF DESCRIPTION OF THE DRAWINGS

FIG. 1 is a cross-sectional view showing a semiconductor device according to a first embodiment;

FIG. 2 is a cross-sectional view along line A-A′ shown in FIG. 1;

FIGS. 3 to 7 are process cross-sectional views showing a method for manufacturing the semiconductor device according to the first embodiment;

FIG. 8 is a cross-sectional view showing a semiconductor device according to a comparative example;

FIG. 9 is a cross-sectional view showing a semiconductor device according to a second embodiment;

FIG. 10 is a cross-sectional view showing a method for manufacturing the semiconductor device according to the second embodiment;

FIG. 11 is a cross-sectional view showing a semiconductor device according to a third embodiment;

FIGS. 12 to 14 are cross-sectional views showing a method for manufacturing the semiconductor device according to the third embodiment;

FIG. 15 is a cross-sectional view showing a semiconductor device according to a fourth embodiment;

FIG. 16 is a cross-sectional view showing a method for manufacturing the semiconductor device according to the fourth embodiment;

FIG. 17 is a cross-sectional view showing a semiconductor device according to a fifth embodiment;

FIG. 18 is a cross-sectional view showing a semiconductor device according to a sixth embodiment;

FIG. 19 is a partially enlarged cross-sectional view showing region C of FIG. 18;

FIG. 20 is a cross-sectional view showing a semiconductor device according to a seventh embodiment;

FIG. 21 is a cross-sectional view along line D-D′ shown in FIG. 20;

FIG. 22 is a cross-sectional view showing a semiconductor device according to an eighth embodiment; and

FIG. 23 is a partially enlarged cross-sectional view showing region E of FIG. 22.

### DETAILED DESCRIPTION

In general, according to one embodiment, a semiconductor device includes a first electrode, a semiconductor part located on the first electrode, a conductive metal-oxide film, a second electrode, an insulating member, and a third electrode located inside the insulating member. The semiconductor part is of a first conductivity type. A first trench and a second trench are formed in an upper surface of the semiconductor part. The first trench and the second trench are separated from each other. The conductive metal-oxide film is located on at least a side surface of the first trench. The conductive metal-oxide film contacts the semiconductor part. The second electrode is located inside the first trench and on the semiconductor part. The second electrode contacts the conductive metal-oxide film and including a metal. The insulating member is located inside the second trench.

### First Embodiment

A semiconductor device according to an embodiment is a semiconductor device for power control and is, for example, a MOSFET (Metal-Oxide-Semiconductor Field-Effect Transistor) with a built-in Schottky barrier diode.

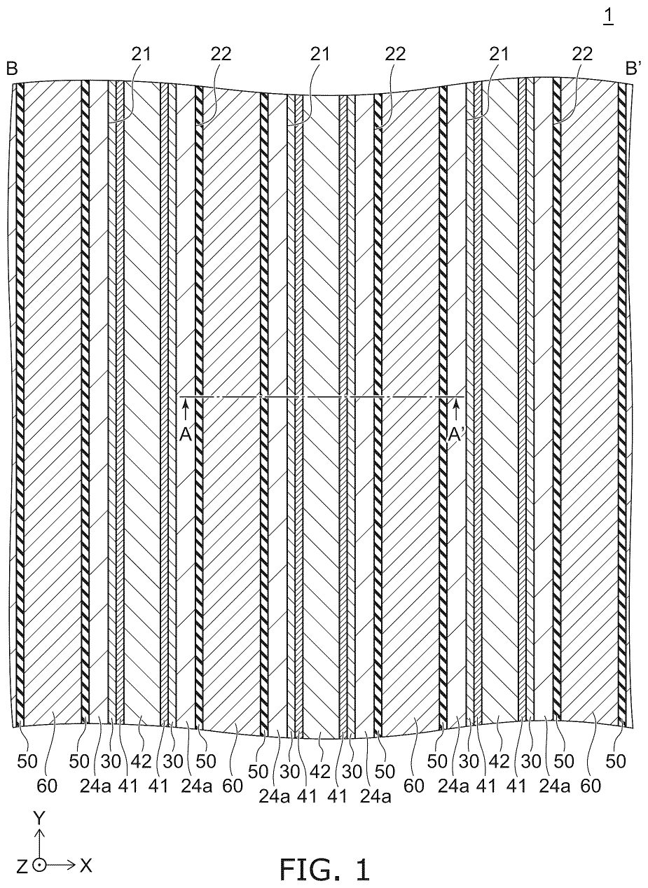

FIG. 1 is a cross-sectional view showing the semiconductor device according to the embodiment.

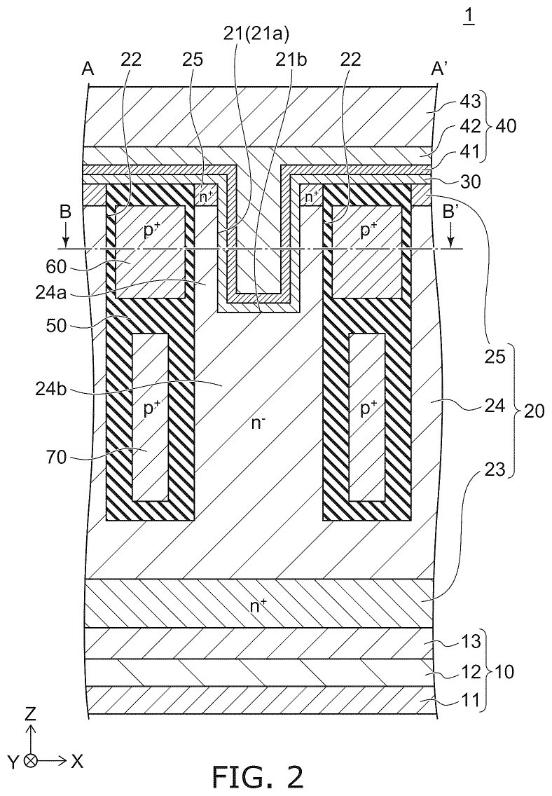

FIG. 2 is a cross-sectional view along line A-A′ shown in FIG. 1.

FIG. 1 is a cross-sectional view along line B-B′ shown in FIG. 2.

As shown in FIGS. 1 and 2, the semiconductor device 1 according to the embodiment includes a drain electrode 10 (a first electrode), a silicon part 20 (a semiconductor part), a titanium oxide film 30 (a conductive metal-oxide film), a source electrode 40 (a second electrode), an insulating member 50, a gate electrode 60 (a third electrode), and a field plate electrode 70 (hereinbelow, referred to as a “FP electrode 70”).

An XYZ orthogonal coordinate system is employed for convenience of description in the specification hereinbelow. The direction from the drain electrode 10 toward the source electrode 40 is referred to as a “Z-direction”; the direction in which the gate electrode 60 and the FP electrode 70 extend is referred to as a “Y-direction” (a second direction); and a direction orthogonal to the Z-direction and Y-direction is referred to as an “X-direction” (a first direction). The Z-direction also is referred to as “up/above”, and the opposite direction also is referred to as “down/below”; however, these expressions are for convenience, and are independent of the direction of gravity.

The drain electrode 10 includes a silver layer 11, a nickel layer 12, and a titanium layer 13 stacked in this order upward from below. The silver layer 11 includes silver (Ag). The nickel layer 12 includes nickel (Ni). The titanium layer 13 includes titanium (Ti). However, the configuration of the drain electrode 10 is not limited thereto.

The silicon part 20 is located on the drain electrode 10 and contacts the titanium layer 13 of the drain electrode 10. The silicon part 20 is made of single-crystal silicon (Si); and the conductivity type of the silicon part 20 is an n-type (a first conductivity type). Source trenches 21 (first trenches) and gate trenches 22 (second trenches) that extend in the Y-direction are formed in the upper surface of the silicon part 20. The source trench 21 and the gate trench 22 are alternately arranged to be separated from each other in the X-direction. The gate trenches 22 are deeper than the source trenches 21.

The silicon part 20 includes a drain layer 23 (a first layer), a drift layer 24 (a second layer), and a source layer 25 (a third layer) stacked in this order. The conductivity type of the drain layer 23 is the n⁺-type; and the drain layer 23 contacts the titanium layer 13 of the drain electrode 10. As a result, the silicon part 20 is connected to the drain electrode 10. In the specification, “connected” refers to an electrical connection.

The drift layer 24 is located on the drain layer 23; and the conductivity type of the drift layer 24 is the n⁻type. In other words, the impurity concentration of the drift layer 24 is less than the impurity concentration of the drain layer 23. The source layer 25 is located on the drift layer 24; and the conductivity type of the source layer 25 is the n⁺-type. In other words, the impurity concentration of the source layer 25 is greater than the impurity concentration of the drift layer 24.

The source trench 21 extends through the source layer 25; and the lower end of the source trench 21 is positioned inside the drift layer 24. The gate trench 22 also extends through the source layer 25; and the lower end of the gate trench 22 is positioned inside the drift layer 24. Therefore, the source layer 25 and the upper part of the drift layer 24 are located between the source trench 21 and the gate trench 22. Hereinbelow, the part of the drift layer 24 positioned between the source trench 21 and the gate trench 22 is referred to as an “upper part 24a” (a first part); and the remaining part of the drift layer 24 is referred to as a “lower part 24b”. The source layer 25 and the upper part 24a of the drift layer 24 have band shapes extending in the Y-direction.

The insulating member 50 is located inside the gate trench 22. The insulating member 50 is made of an insulating material, and is made of, for example, silicon oxide (SiO₂). The insulating member 50 contacts the entire inner surface of the gate trench 22.

The gate electrode 60 is located inside the insulating member 50. The gate electrode 60 has a beam shape extending in the Y-direction. The gate electrode 60 is made of p⁺-type polysilicon. The gate electrode 60 faces the upper part 24a of the drift layer 24 via a portion of the insulating member 50.

The FP electrode 70 is located below the gate electrode 60 inside the insulating member 50. The FP electrode 70 has a band shape extending in the Y-direction. The FP electrode 70 is separated from the gate electrode 60 and faces the lower part 24b of the drift layer 24 via a portion of the insulating member 50. The FP electrode 70 is made of p⁺-type polysilicon. The FP electrode 70 is connected to the source electrode 40.

The titanium oxide film 30 is located on the entire inner surface of the source trench 21, i.e., on a side surface 21a and a bottom surface 21b of the source trench 21. The titanium oxide film 30 also is located on the insulating member 50 and on the silicon part 20. The titanium oxide film 30 contacts the insulating member 50, the source layer 25, and the upper and lower parts 24a and 24b of the drift layer 24.

The titanium oxide film 30 is a conductive metal-oxide film. The composition of the titanium oxide film can be expressed as TiOₓ, in which x is, for example, 0.5 to 2.5, or 1.8 to 2.2. The resistivity of the titanium oxide film 30 is, for example, about 0.1 Ω·cm. It is favorable for the thickness of the titanium oxide film 30 to be not more than 20 nm. A conductive metal-oxide film that has another composition may be included instead of a titanium oxide film. In such a case, it is favorable for the resistivity of the conductive metal-oxide film to be not more than 1 kΩ·cm. It is favorable for the conductive metal-oxide film to include, for example, at least one metal oxide selected from the group consisting of titanium oxide (TiOₓ), zinc oxide (ZnO), magnesium oxide (MgO), and aluminum oxide (Al₂O₃).

The source electrode 40 includes a platinum layer 41 (a first metal layer), a tungsten layer 42, and an aluminum layer 43 stacked in this order. The platinum layer 41 includes platinum (Pt), and is located on the titanium oxide film 30. The platinum layer 41 contacts the titanium oxide film 30 and is located on the entire inner surface of the source trench 21, on the upper surface of the silicon part 20, and on the upper surface of the insulating member 50 with the titanium oxide film 30 interposed. The work function of the platinum layer 41 is about 5.7 eV. Although a layer that is made of another metal, metal nitride, or metal oxide may be included instead of the platinum layer 41, it is favorable for the work function of the layer to be not less than 4.7 eV. Examples of the other metal include iridium, nickel, cobalt, tungsten, etc. Examples of the metal nitride include vanadium nitride, molybdenum nitride, titanium nitride, etc.

The tungsten layer 42 includes tungsten (W) and is located on the platinum layer 41. The tungsten layer 42 contacts the platinum layer 41 and is located on the silicon part 20, on the insulating member 50, and inside the source trench 21. The work function of the tungsten layer 42 is about 4.7 eV and is less than the work function of the platinum layer 41. The aluminum layer 43 includes aluminum (Al) and is located on the tungsten layer 42. The aluminum layer 43 contacts the tungsten layer 42.

By such a configuration, the interior of the source trench 21 is filled with a portion of the titanium oxide film 30, a portion of the platinum layer 41, and a portion of the tungsten layer 42. Another portion of the titanium oxide film 30, another portion of the platinum layer 41, another portion of the tungsten layer 42, and the aluminum layer 43 are stacked in this order on the silicon part 20 and on the insulating member 50.

The titanium oxide film 30 has an ohmic connection with the source layer 25 of the silicon part 20 at the upper surface of the silicon part 20. The source layer 25 is connected to the upper part 24a of the drift layer 24. As a result, a MOSFET (Metal-Oxide-Semiconductor Field-Effect Transistor) is formed of the source electrode 40, the gate electrode 60, the insulating member 50, the upper part 24a of the drift layer 24, and the source layer 25.

Also, the titanium oxide film 30 has a Schottky junction with the drift layer 24 at the side surface 21a and the bottom surface 21b of the source trench 21. As a result, a Schottky barrier diode is formed in which the source electrode 40 is used as an anode, and the drift layer 24 is used as a cathode.

A method for manufacturing the semiconductor device 1 according to the embodiment will now be described.

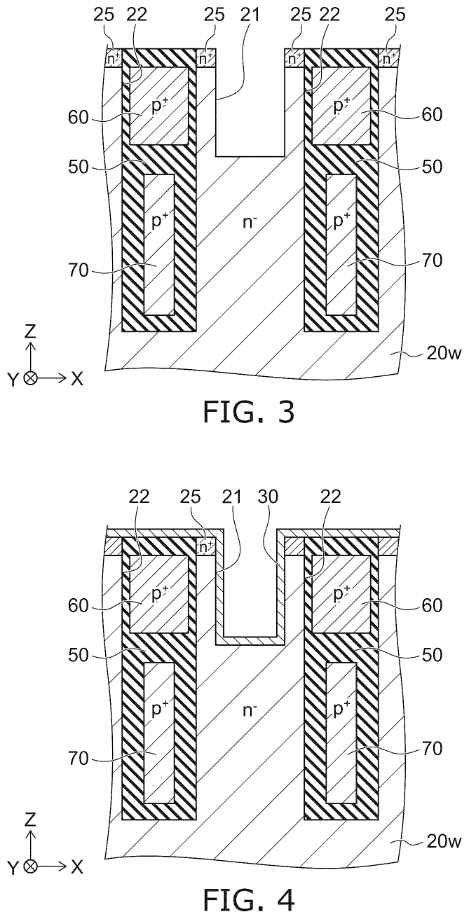

FIGS. 3 to 7 are process cross-sectional views showing the method for manufacturing the semiconductor device according to the embodiment.

First, a silicon wafer 20w is prepared as shown in FIG. 3. The conductivity type of the lower part (not illustrated) of the silicon wafer 20w is the n⁺-type; and the conductivity type of the upper part of the silicon wafer 20w is the n⁻type. Then, an impurity that forms donors is ion-implanted into the upper layer part of the silicon wafer 20w. The source layer 25 is formed thereby. Then, the multiple gate trenches 22 are formed in the upper surface of the silicon wafer 20w. Each gate trench 22 extends in the Y-direction; and the multiple gate trenches 22 are separated from each other in the X-direction. Then, the insulating member 50, the FP electrode 70, and the gate electrode 60 are formed inside the gate trench 22. Then, the source trenches 21 are formed between the gate trenches 22 adjacent to each other at the upper surface of the silicon wafer 20w. The source trenches 21 are separated from the gate trench 22 and extend in the Y-direction.

Then, as shown in FIG. 4, titanium oxide is deposited on the entire surface by, for example, ALD (Atomic Layer Deposition). As a result, the titanium oxide film 30 is formed in a layer shape on the upper surface of the silicon wafer 20w, on the upper surface of the insulating member 50, and on the inner surface of the source trench 21.

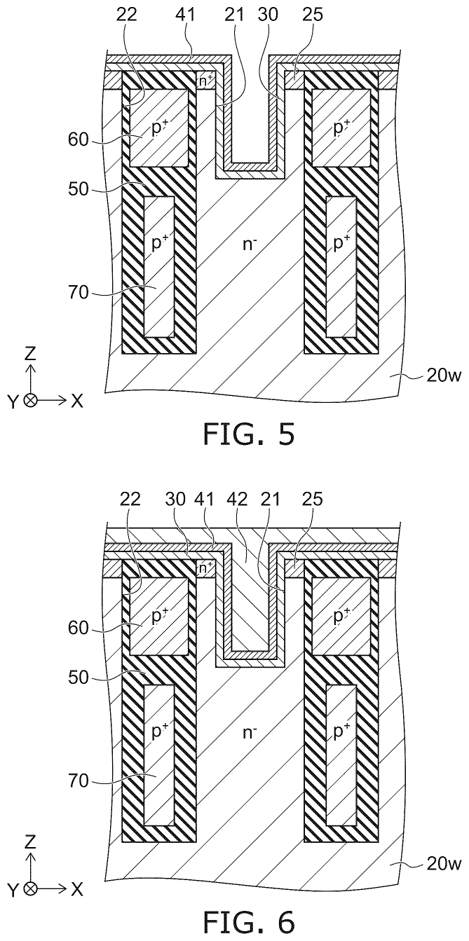

Continuing as shown in FIG. 5, platinum is deposited on the entire surface by, for example, ALD. As a result, the platinum layer 41 is formed in a layer shape on the titanium oxide film 30. As a result, the two-layer film made of the titanium oxide film 30 and the platinum layer 41 covers the upper surface of the silicon wafer 20w, the upper surface of the insulating member 50, and the entire inner surface of the source trench 21. At this time, the titanium oxide film 30 and the platinum layer 41 do not completely fill the interior of the source trench 21; and a space remains inside the source trench 21.

Then, as shown in FIG. 6, tungsten is deposited on the entire surface by, for example, CVD (Chemical Vapor Deposition). The deposition amount of the tungsten is such that the entire interior of the source trench 21 is filled. As a result, the tungsten layer 42 is formed on the platinum layer 41. The interior of the source trench 21 is filled with a portion of the tungsten layer 42 with the titanium oxide film 30 and the platinum layer 41 interposed.

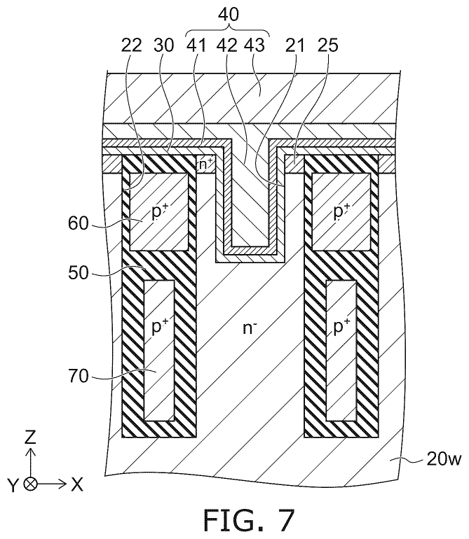

Continuing as shown in FIG. 7, aluminum is deposited on the entire surface by, for example, sputtering. As a result, the aluminum layer 43 is formed on the tungsten layer 42. As described above, the interior of the source trench 21 is already filled with the titanium oxide film 30, the platinum layer 41, and a portion of the tungsten layer 42, and so the aluminum layer 43 is not located inside the source trench 21. The source electrode 40 is formed of the platinum layer 41, the tungsten layer 42, and the aluminum layer 43.

Then, as shown in FIG. 2, the silicon wafer 20w is thinned by polishing from the lower surface of the silicon wafer 20w. Then, the titanium layer 13, the nickel layer 12, and the silver layer 11 are formed in this order on the lower surface of the silicon wafer 20w. The drain electrode 10 is formed thereby. Then, the silicon wafer 20w is singulated into multiple silicon parts 20 by dicing. At this time, the lowermost part of the silicon wafer 20w becomes the drain layer 23; the uppermost portion of the silicon wafer 20w becomes the source layer 25; and the part of the silicon wafer 20w between the drain layer 23 and the source layer 25 becomes the drift layer 24. Thus, the semiconductor device 1 is manufactured.

Operations of the semiconductor device 1 according to the embodiment will now be described.

A higher potential than that of the source electrode 40 is applied to the drain electrode 10. At this time, the potential of the FP electrode 70 becomes equal to the potential of the source electrode 40. In this state, for example, when the same potential as that of the source electrode 40 is applied to the gate electrode 60, a depletion layer spreads from the starting points of the interface between the titanium oxide film 30 and the drift layer 24 and the interface between the insulating member 50 and the drift layer 24; and the entire upper part 24a of the drift layer 24 is depleted. As a result, the semiconductor device 1 is set to an off-state.

When a potential that is greater than a threshold Vth is applied to the gate electrode 60, an accumulation layer is formed at the part of the upper part 24a of the drift layer 24 contacting the insulating member 50; and a current starts to flow. As a result, a current flows through the path of the drain electrode 10, the drain layer 23 of the silicon part 20, the lower part 24b of the drift layer 24, the accumulation layer of the upper part 24a of the drift layer 24, the source layer 25, and the source electrode 40; and the semiconductor device 1 is switched to an on-state.

When the semiconductor device 1 is switched from the on-state to the off-state, the electrons that are present inside the drift layer 24 are discharged into the drain electrode 10 via the drain layer 23. When avalanche breakdown occurs, the electrons that are generated are discharged into the drain electrode 10 via the drain layer 23; and the holes that are generated are discharged into the source electrode 40 via the side surface 21a and the bottom surface 21b of the source trench 21.

When a potential that is higher than the drain electrode 10 is applied to the source electrode 40, a current flows through the path of the source electrode 40, the titanium oxide film 30, the lower part 24b of the drift layer 24, the drain layer 23, and the drain electrode 10 via a Schottky barrier diode formed at the bottom surface 21b of the source trench 21. As a result, for example, a free wheel current can flow.

Effects of the embodiment will now be described.

According to the embodiment, the conductivity type of the upper part 24a of the drift layer 24 is the n⁻type; and the source electrode 40 and the gate electrode 60 generate a depletion layer in the upper part 24a; therefore, the MOSFET of the semiconductor device 1 is normally-off. The conduction of the MOSFET is controlled by controlling the potential of the gate electrode 60. As a result, the reverse recovery charge can be reduced because there is no p-n junction in the silicon part 20; and no hole injection occurs during the reverse recovery operation.

According to the embodiment, the platinum layer 41 is located on the side surface 21a of the source trench 21. Because the work function of platinum is greater than the work function of tungsten, the barrier height between the platinum layer 41 and the drift layer 24 can be increased by using the platinum layer 41 as a high-work function member. As the barrier height increases, the effect of depleting the drift layer 24 can be increased, and the threshold of the MOSFET can be increased. If, however, the platinum layer 41 directly contacts the drift layer 24, Fermi level pinning undesirably causes the barrier height between the platinum layer 41 and the drift layer 24 to be less than the value that would be expected from the work function of platinum.

Therefore, according to the embodiment, the titanium oxide film 30 is interposed between the platinum layer 41 and the drift layer 24. The presence of the titanium oxide film 30 relaxes Fermi level pinning of the platinum layer 41; and the barrier height between the platinum layer 41 and the drift layer 24 can be adjusted to a value corresponding to the work function of platinum. As a result, the threshold of the MOSFET can be adjusted to the desired value.

Because the titanium oxide film 30 is conductive, the resistance of the Schottky barrier diode can be reduced. Thus, according to the embodiment, the threshold of the MOSFET can be adjusted to the prescribed value while maintaining a low resistance of the Schottky barrier diode.

By interposing the titanium oxide film 30 between the platinum layer 41 and the silicon part 20, the occurrence of crystal defects in the silicon part 20 due to thermal stress between the platinum layer 41 and the silicon part 20 can be suppressed. Also, the platinum atoms included in the platinum layer 41 can be prevented from being trapped in crystal defects originally present in the silicon part 20. A leakage current between the drain and source can be suppressed thereby. Furthermore, by interposing the titanium oxide film 30 between the platinum layer 41 and the insulating member 50, the adhesion between the platinum layer 41 and the insulating member 50 can be improved.

According to the embodiment, the FP electrode 70 is located below the gate electrode 60 inside the insulating member 50. As a result, an electric field is not easily applied to the upper part 24a of the drift layer 24; and the upper part 24a is more easily depleted. As a result, the threshold of the MOSFET is increased.

### Comparative Example

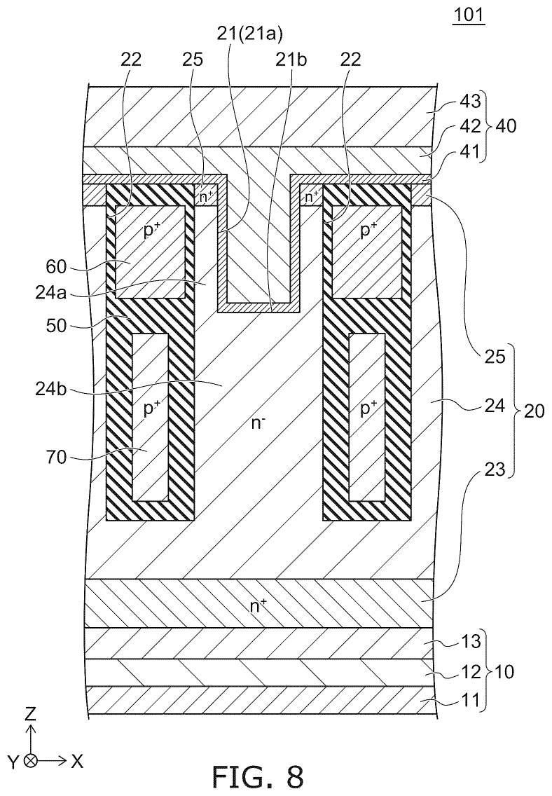

FIG. 8 is a cross-sectional view showing a semiconductor device according to a comparative example.

As shown in FIG. 8, the semiconductor device 101 according to the comparative example differs from the semiconductor device 1 according to the first embodiment in that the titanium oxide film 30 is not included.

In the semiconductor device 101, the platinum layer 41 of the source electrode 40 contacts the silicon part 20 and the insulating member 50 because the titanium oxide film 30 is not included. As a result, the barrier height between the platinum layer 41 and the drift layer 24 is less than the value expected from the work function of platinum due to the effects of Fermi level pinning. As a result, the effect of spreading the depletion layer is reduced, and the threshold of the MOSFET is undesirably reduced.

It also may be considered to relax Fermi level pinning by providing an insulating film such as a silicon oxide film, a silicon nitride film, etc., between the platinum layer 41 and the silicon part 20. However, in such a case, the resistance of the Schottky barrier diode at the bottom surface 21b of the source trench 21 is undesirably increased.

Crystal defects in the silicon part 20 due to thermal stress between the platinum layer 41 and the silicon part 20 also occur easily. The platinum atoms included in the platinum layer 41 are easily trapped in the crystal defects of the silicon part 20, and the leakage current between the drain and source is increased. The platinum layer 41 detaches more easily from the insulating member 50 because the adhesion between the platinum layer 41 and the insulating member 50 is poor.

### Second Embodiment

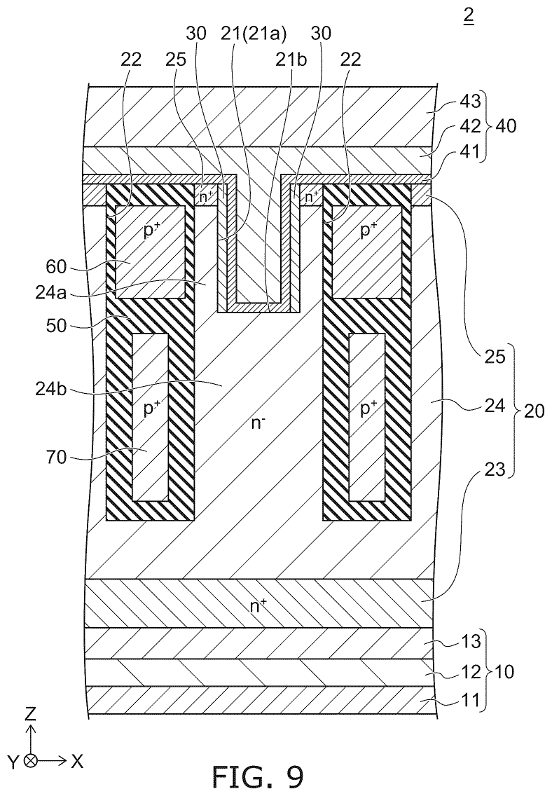

FIG. 9 is a cross-sectional view showing a semiconductor device according to an embodiment.

As shown in FIG. 9, the semiconductor device 2 according to the embodiment differs from the semiconductor device 1 according to the first embodiment in that the titanium oxide film 30 is not located on the bottom surface 21b of the source trench 21, on the insulating member 50, or on the silicon part 20.

Therefore, the platinum layer 41 of the source electrode 40 contacts the lower part 24b of the drift layer 24 at the bottom surface 21b of the source trench 21. The platinum layer 41 also contacts the source layer 25 and the insulating member 50.

A method for manufacturing the semiconductor device 2 according to the embodiment will now be described.

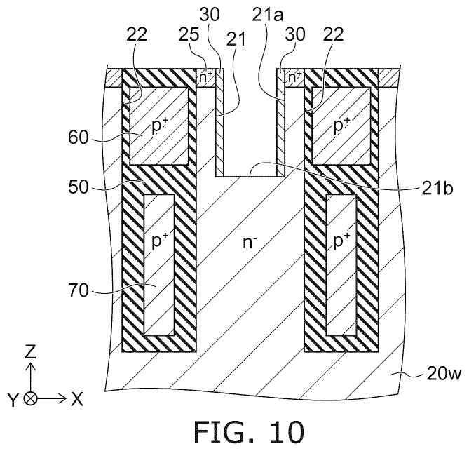

FIG. 10 is a cross-sectional view showing the method for manufacturing the semiconductor device according to the embodiment.

First, the processes shown in FIGS. 3 and 4 are performed.

Then, as shown in FIG. 10, the part of the titanium oxide film 30 deposited on the bottom surface 21b of the source trench 21, the part of the titanium oxide film 30 deposited on the silicon wafer 20w, and the part of the titanium oxide film 30 deposited on the insulating member 50 are removed by performing, for example, anisotropic etching such as RIE (Reactive Ion Etching), etc. At this time, the part of the titanium oxide film 30 deposited on the side surface 21a of the source trench 21 remains.

The subsequent processes are similar to those of the first embodiment. Specifically, processes similar to the processes shown in FIGS. 5 to 7 are performed, and then the silicon wafer 20w is thinned by polishing the lower surface of the silicon wafer 20w, forming the drain electrode 10 as shown in FIG. 9, and singulating the silicon wafer 20w by dicing. Thus, the semiconductor device 2 according to the embodiment is manufactured.

According to the embodiment as well, the titanium oxide film 30 is interposed between the platinum layer 41 and the upper part 24a of the drift layer 24, and so the effect of relaxing Fermi level pinning of the platinum layer 41 is obtained, and the threshold of the MOSFET can be adjusted to the desired value. On the other hand, the titanium oxide film 30 is not interposed between the platinum layer 41 and the source layer 25, and so an effect of relaxing Fermi level pinning is not obtained, and an ohmic connection between the platinum layer 41 and the source layer 25 is formed more easily due to a reduction of the barrier height. As a result, the on-resistance of the MOSFET can be reduced.

Because the titanium oxide film 30 is not interposed between the platinum layer 41 and the lower part 24b of the drift layer 24, the effect of relaxing Fermi level pinning cannot be obtained, and the barrier height between the platinum layer 41 and the lower part 24b of the drift layer 24 is reduced. However, the lower part 24b of the drift layer 24 is a part included in the Schottky barrier diode and not in the MOSFET, and so the threshold of the MOSFET is not affected, and the forward voltage (Vf) of the Schottky barrier diode is reduced. As a result, the conduction loss of the Schottky barrier diode can be reduced. Otherwise, the configuration, manufacturing method, operations, and effects according to the embodiment are similar to those of the first embodiment.

### Third Embodiment

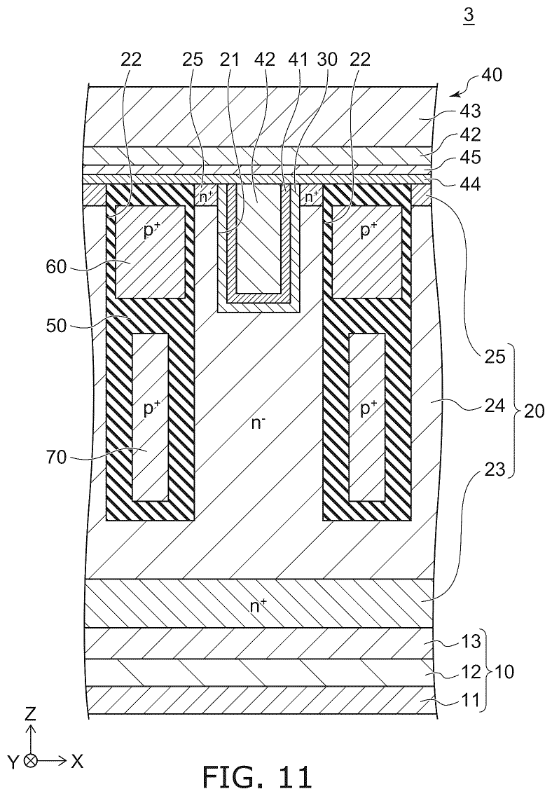

FIG. 11 is a cross-sectional view showing a semiconductor device according to an embodiment.

As shown in FIG. 11, the semiconductor device 3 according to the embodiment differs from the semiconductor device 1 according to the first embodiment in that the titanium oxide film 30 is not located on the insulating member 50 or on the silicon part 20, and the source electrode 40 includes a titanium layer 44 (a second metal layer) and a titanium nitride layer 45.

The titanium layer 44 includes titanium and is located on the part of the source electrode 40 located inside the source trench 21, on the silicon part 20, and on the insulating member 50. The titanium layer 44 contacts the tungsten layer 42, the platinum layer 41, the titanium oxide film 30, the source layer 25, and the insulating member 50. The titanium nitride layer 45 includes titanium nitride (TiN) and is located on the titanium layer 44. The titanium layer 44 and the titanium nitride layer 45 are substantially flat, and are parallel to the XY-plane. The tungsten layer 42 is located on the titanium nitride layer 45; and the aluminum layer 43 is located on the tungsten layer 42.

A method for manufacturing the semiconductor device 3 according to the embodiment will now be described.

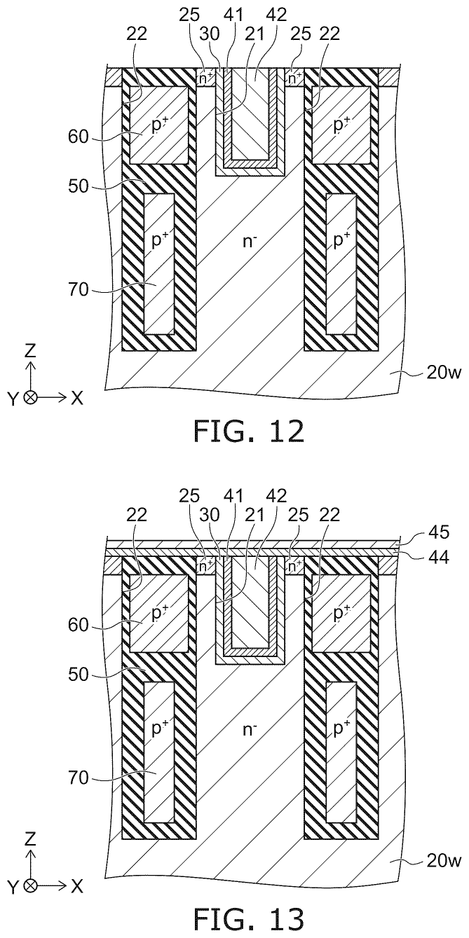

FIGS. 12 to 14 are cross-sectional views showing the method for manufacturing the semiconductor device according to the embodiment.

First, the processes shown in FIGS. 3 to 6 are performed.

Then, as shown in FIG. 12, planarization is performed using, for example, etching such as RIE or the like, CMP (Chemical Mechanical Polishing), etc. The parts of the tungsten layer 42, the platinum layer 41, and the titanium oxide film 30 deposited on the silicon part 20 and on the insulating member 50 are removed. As a result, the upper surface of the silicon part 20 and the upper surface of the insulating member 50 are exposed. The titanium oxide film 30, the platinum layer 41, and the tungsten layer 42 remain inside the source trench 21.

Continuing as shown in FIG. 13, the titanium layer 44 is formed by depositing titanium by, for example, sputtering. Then, the titanium nitride layer 45 is formed by depositing titanium nitride by, for example, sputtering.

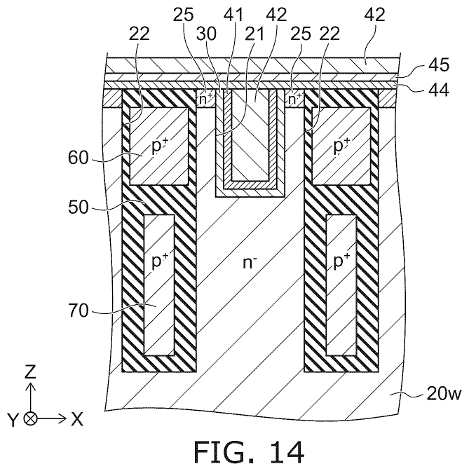

Then, as shown in FIG. 14, the tungsten layer 42 is formed on the titanium nitride layer 45 by depositing tungsten by, for example, CVD. As a result, the tungsten layer 42 is separately formed above and below the titanium layer 44 and the titanium nitride layer 45. In other words, the tungsten layer 42 that is deposited in the process shown in FIG. 6 and has a portion removed in the process shown in FIG. 12 is located below the titanium layer 44 and the titanium nitride layer 45; and the tungsten layer 42 that is deposited in the process shown in FIG. 14 is located above the titanium layer 44 and the titanium nitride layer 45.

The subsequent processes are similar to those of the first embodiment. In other words, the aluminum layer 43 is formed as shown in FIG. 7; the silicon wafer 20w is thinned by polishing the lower surface of the silicon wafer 20w and the drain electrode 10 is formed as shown in FIG. 11; and the silicon wafer 20w is singulated by dicing. Thus, the semiconductor device 3 according to the embodiment is manufactured.

According to the embodiment, the source layer 25 that is made of n⁺-type silicon contacts the titanium layer 44. The work function of titanium (e.g., about 4.3 eV) is less than the work function of platinum (e.g., about 5.7 eV), and so the ohmic connection between the source electrode 40 and the source layer 25 is formed more easily. As a result, the on-resistance of the MOSFET is reduced. On the other hand, the upper part 24a of the drift layer 24 that is made of n⁻type silicon faces the platinum layer 41 via the titanium oxide film 30. The work function of platinum is greater than the work function of tungsten, and so the threshold of the MOSFET is increased. Otherwise, the configuration, manufacturing method, operations, and effects according to the embodiment are similar to those of the first embodiment.

### Fourth Embodiment

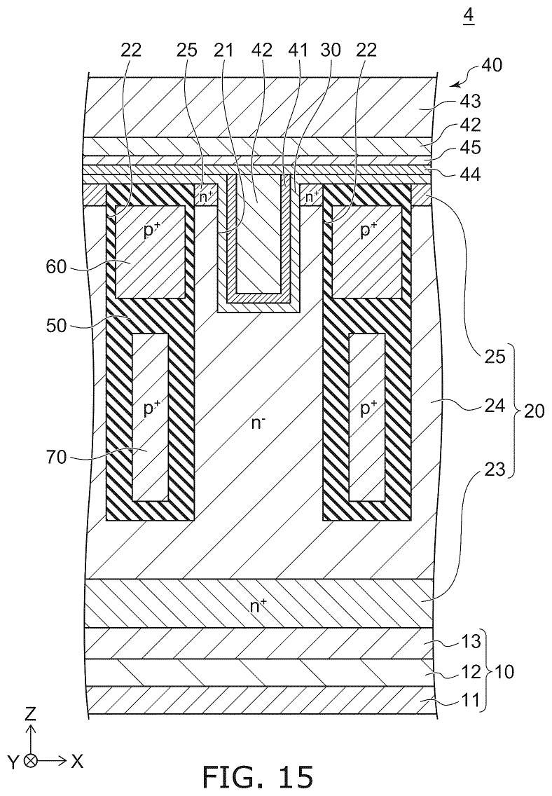

FIG. 15 is a cross-sectional view showing a semiconductor device according to an embodiment.

As shown in FIG. 15, the semiconductor device 4 according to the embodiment differs from the semiconductor device 3 according to the third embodiment in that the titanium oxide film 30 is located on the silicon part 20 and on the insulating member 50. In the semiconductor device 4, the titanium layer 44 is separated from the silicon part 20 and the insulating member 50 with the titanium oxide film 30 interposed. The part of the titanium oxide film 30 that is located on the silicon part 20 and faces the source layer 25 contacts the titanium layer 44; and the part of the titanium oxide film 30 that is located inside the source trench 21 and faces the drift layer 24 contacts the platinum layer 41.

A method for manufacturing the semiconductor device 4 according to the embodiment will now be described.

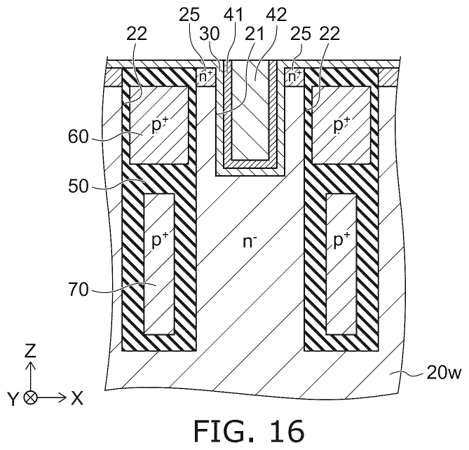

FIG. 16 is a cross-sectional view showing a method for manufacturing the semiconductor device according to the embodiment.

First, the processes shown in FIGS. 3 to 6 are performed.

Then, as shown in FIG. 16, the parts of the tungsten layer 42 and the platinum layer 41 deposited on the silicon part 20 and on the insulating member 50 are removed by performing, for example, RIE or CMP. At this time, the titanium oxide film 30 remains on the silicon part 20 and on the insulating member 50. As a result, the titanium oxide film 30 that is on the silicon part 20 and on the insulating member 50 is exposed. The titanium oxide film 30, the platinum layer 41, and the tungsten layer 42 remain inside the source trench 21.

The subsequent processes are similar to those of the third embodiment. Specifically, the titanium layer 44 and the titanium nitride layer 45 are formed as shown in FIG. 13; the tungsten layer 42 is formed as shown in FIG. 14; the aluminum layer 43 is formed as shown in FIG. 15; the silicon wafer 20w is thinned by polishing the lower surface of the silicon wafer 20w; the drain electrode 10 is formed; and the silicon wafer 20w is singulated by dicing. Thus, the semiconductor device 4 according to the embodiment is manufactured.

According to the embodiment, the source layer 25 contacts the titanium oxide film 30, but the titanium layer 44 and the titanium nitride layer 45 are present on the titanium oxide film 30. In the case of titanium, Fermi level pinning causes the barrier height to be greater than a barrier height commensurate with the original work function; however, when the Fermi level pinning is relaxed by the titanium oxide film 30, the barrier height is a low barrier height commensurate with the original work function of titanium, and so the ohmic connection between the source electrode 40 and the source layer 25 is formed more easily. As a result, the on-resistance of the MOSFET is reduced. Otherwise, the configuration, manufacturing method, operations, and effects according to the embodiment are similar to those of the third embodiment.

### Fifth Embodiment

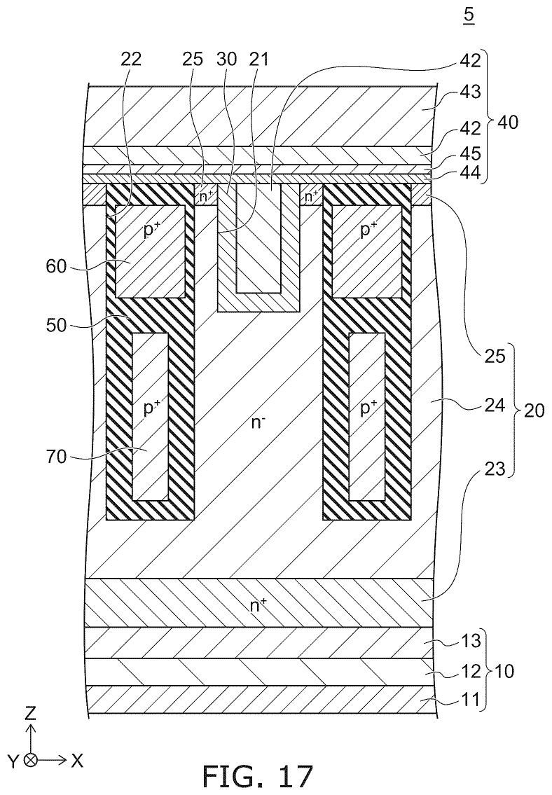

FIG. 17 is a cross-sectional view showing a semiconductor device according to an embodiment.

As shown in FIG. 17, the semiconductor device 5 according to the embodiment differs from the semiconductor device 3 according to the third embodiment in that the source electrode 40 does not include the platinum layer 41. In the semiconductor device 5, the titanium oxide film 30 contacts the tungsten layer 42. The titanium oxide film 30 of the semiconductor device 5 may be thicker than that of the semiconductor device 3. The method for manufacturing the semiconductor device 5 differs from the method for manufacturing the semiconductor device 3 according to the third embodiment in that the process of forming the platinum layer 41 shown in FIG. 5 is not performed.

According to the embodiment, the titanium oxide film 30 is used as a high-work function member instead of the platinum layer 41. The work function of titanium oxide is, for example, about 5.1 eV, which is greater than the work function of platinum. Because Fermi level pinning does not occur easily at the titanium oxide film 30, effects similar to those of the third embodiment can be obtained. Otherwise, the configuration, manufacturing method, operations, and effects according to the embodiment are similar to those of the third embodiment.

### Sixth Embodiment

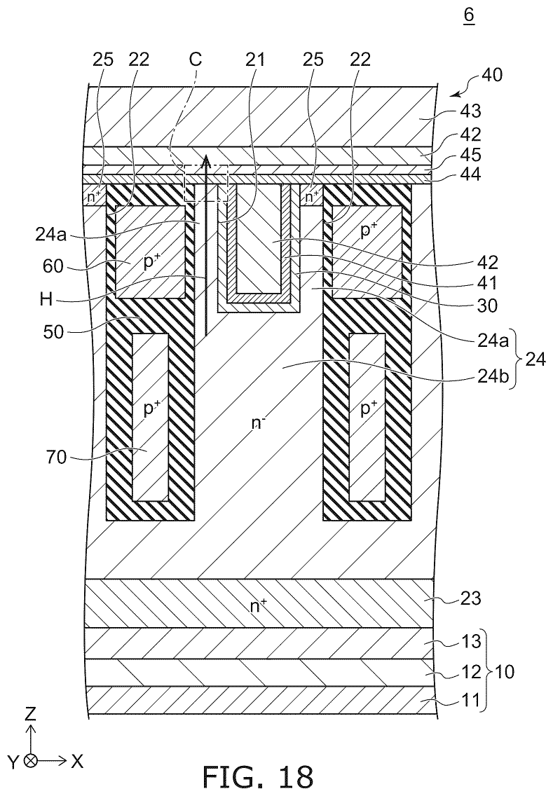

FIG. 18 is a cross-sectional view showing a semiconductor device according to an embodiment.

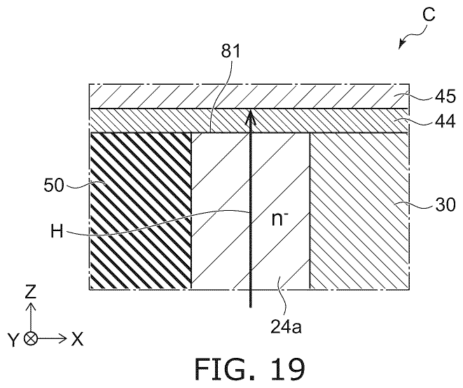

FIG. 19 is a partially enlarged cross-sectional view showing region C of FIG. 18.

As shown in FIGS. 18 and 19, the semiconductor device 6 according to the embodiment differs from the semiconductor device 3 according to the third embodiment in that the source layer 25 is not located above the upper part 24a for every other upper part 24a arranged in the X-direction in the drift layer 24. For the upper part 24a above which the source layer 25 is not located, the upper surface of the upper part 24a contacts and has a Schottky junction with the lower surface of the titanium layer 44 of the source electrode 40. In other words, a contact surface 81 between the titanium layer 44 and the upper part 24a of the drift layer 24 is a Schottky junction surface.

According to the embodiment, as illustrated by a path H in FIGS. 18 and 19, holes that are generated when avalanche breakdown occurs are discharged from the upper part 24a of the drift layer 24 into the source electrode 40 via the contact surface 81. The holes are easily discharged through the path H because the titanium oxide film 30, which has a higher resistivity than the source electrode 40, is not interposed, and the source layer 25, which has a higher impurity concentration than the drift layer 24, is not interposed. As a result, the holes that are generated during breakdown are more quickly discharged, and fluctuation of the characteristics of the semiconductor device 6 can be suppressed. Otherwise, the configuration, manufacturing method, operations, and effects according to the embodiment are similar to those of the third embodiment.

### Seventh Embodiment

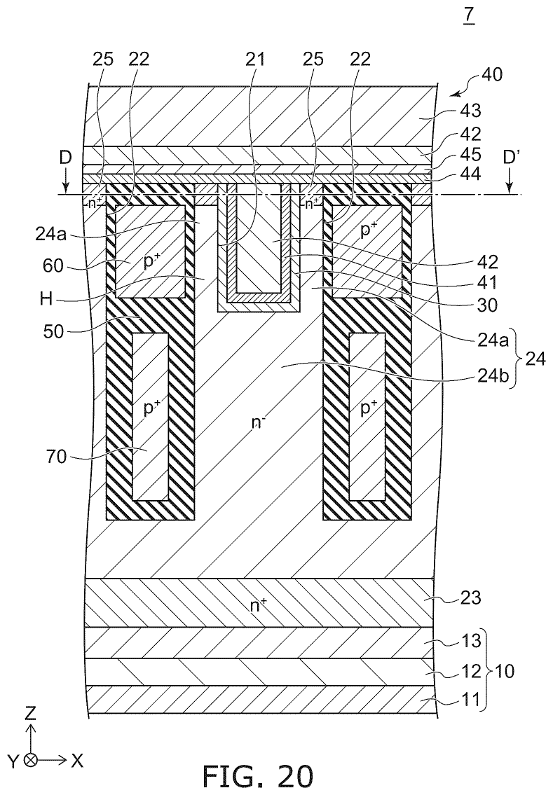

FIG. 20 is a cross-sectional view showing a semiconductor device according to an embodiment.

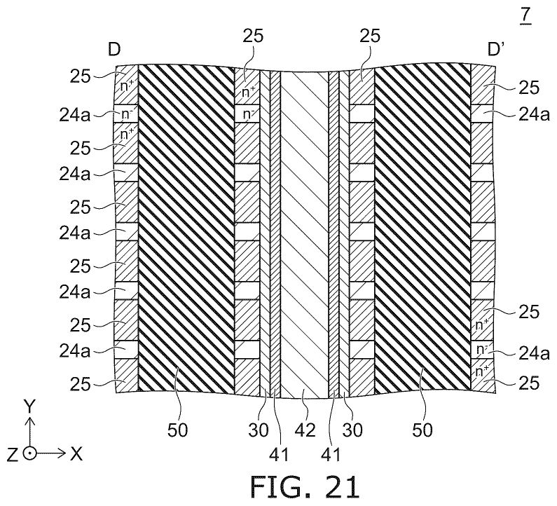

FIG. 21 is a cross-sectional view along line D-D′ shown in FIG. 20.

As shown in FIGS. 20 and 21, the semiconductor device 7 according to the embodiment differs from the semiconductor device 3 according to the third embodiment in that the source layers 25 are discontinuously arranged along the Y-direction. For the parts of the upper part 24a of the drift layer 24 above which the source layer 25 is not located, the upper surface of the upper part 24a contacts and has a Schottky junction with the lower surface of the titanium layer 44. When viewed along the Z-direction, the contact surface 81 between the titanium layer 44 and the upper part 24a of the drift layer 24 is arranged in a matrix configuration.

According to the embodiment as well, similarly to the sixth embodiment, holes that are generated when avalanche breakdown occurs are directly discharged from the upper part 24a of the drift layer 24 into the source electrode 40 via the contact surface 81 without passing through the titanium oxide film 30 and the source layer 25. As a result, fluctuation of the characteristics of the semiconductor device 7 during breakdown can be suppressed. Otherwise, the configuration, manufacturing method, operations, and effects according to the embodiment are similar to those of the third embodiment. The contact surface 81 may be arranged in a staggered configuration when viewed along the Z-direction.

### Eighth Embodiment

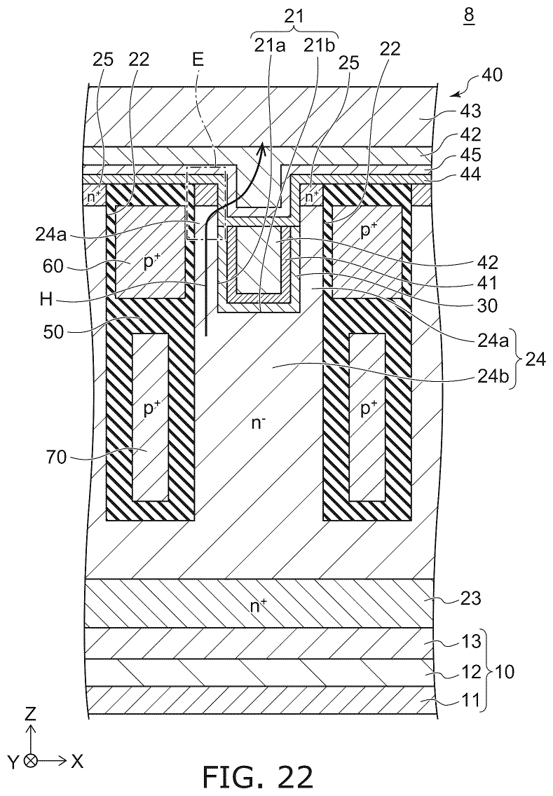

FIG. 22 is a cross-sectional view showing a semiconductor device according to an embodiment.

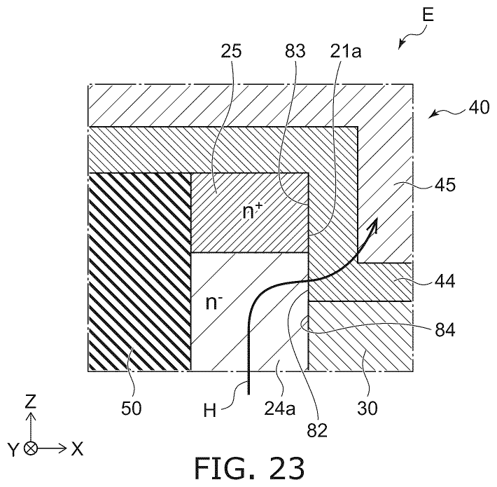

FIG. 23 is a partially enlarged cross-sectional view showing region E of FIG. 22.

As shown in FIGS. 22 and 23, the semiconductor device 8 according to the embodiment differs from the semiconductor device 3 according to the third embodiment in that the parts of the titanium oxide film 30, the platinum layer 41, and the tungsten layer 42 located lower than the titanium layer 44 and the titanium nitride layer 45 are located only in the lower part of the source trench 21. A portion of the titanium layer 44, a portion of the titanium nitride layer 45, and a portion of a part of the tungsten layer 42 located higher than the titanium layer 44 and the titanium nitride layer 45 are located in the upper part of the source trench 21.

As a result, the titanium layer 44 contacts and forms a contact surface 82 with the upper part 24a of the drift layer 24 at a portion of the side surface 21a of the source trench 21. The contact surface 82 is a Schottky junction surface. The contact surface 82 is positioned lower than a contact surface 83 between the titanium layer 44 and the source layer 25 and positioned higher than a contact surface 84 between the titanium oxide film 30 and the upper part 24a. The contact surface 83 is an ohmic junction surface; and the contact surface 84 is a Schottky junction surface.

A method for manufacturing the semiconductor device 8 according to the embodiment will now be described.

First, the processes shown in FIGS. 3 to 6 are performed.

Then, the process shown in FIG. 12 is performed.

Continuing, the titanium oxide film 30, the platinum layer 41, and the tungsten layer 42 are etched to be removed from the upper part of the source trench 21. At this time, the titanium oxide film 30, the platinum layer 41, and the tungsten layer 42 remain in the lower part of the source trench 21.

The subsequent processes are similar to those of the third embodiment. In other words, the titanium layer 44 and the titanium nitride layer 45 are formed as shown in FIG. 13; the aluminum layer 43 is formed as shown in FIG. 7; the silicon wafer 20w is thinned by polishing the lower surface of the silicon wafer 20w, and the drain electrode 10 is formed as shown in FIG. 11; and the silicon wafer 20w is singulated by dicing. Thus, the semiconductor device 8 according to the embodiment is manufactured.

According to the embodiment as well, similarly to the sixth embodiment, holes that are generated when avalanche breakdown occurs are discharged into the source electrode 40 via the contact surface 82 between the titanium layer 44 and the upper part 24a of the drift layer 24. Fluctuation of the characteristics of the semiconductor device 8 can be suppressed thereby. Otherwise, the configuration, manufacturing method, operations, and effects according to the embodiment are similar to those of the third embodiment.

According to the embodiments above, a semiconductor device can be realized in which the threshold of the transistor part can be a prescribed value while maintaining a low resistance of the diode part.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

Embodiments include the following aspects.

### Note 1

A semiconductor device, comprising:
a first electrode;
a semiconductor part located on the first electrode, the semiconductor part being of a first conductivity type, a first trench and a second trench being formed in an upper surface of the semiconductor part, the first trench and the second trench being separated from each other;
a conductive metal-oxide film located on at least a side surface of the first trench, the conductive metal-oxide film contacting the semiconductor part;
a second electrode located inside the first trench and on the semiconductor part, the second electrode contacting the conductive metal-oxide film and including a metal;
an insulating member located inside the second trench; and
a third electrode located inside the insulating member.

### Note 2

The device according to note 1, wherein
a resistivity of the conductive metal-oxide film is not more than 1 kΩ·cm.

### Note 3

The device according to note 1 or 2, wherein
the conductive metal-oxide film includes at least one metal oxide selected from the group consisting of titanium oxide, zinc oxide, magnesium oxide, and aluminum oxide.

### Note 4

The device according to note 3, wherein
the conductive metal-oxide film includes titanium oxide.

### Note 5

The device according to any one of notes 1-4, wherein
a thickness of the conductive metal-oxide film is not more than 20 nm.

### Note 6

The device according to any one of notes 1-5, wherein
a work function of a part of the second electrode contacting at least the conductive metal-oxide film is not less than 4.7 eV.

Note 7

### The Device According to Any One of Notes 1-6, Wherein

a part of the second electrode contacting at least the conductive metal-oxide film includes at least one type of material selected from the group consisting of platinum, iridium, nickel, cobalt, tungsten, vanadium nitride, molybdenum nitride, and titanium nitride.

### Note 8

The device according to any one of notes 1-7, wherein
the conductive metal-oxide film is located also on a bottom surface of the first trench, and
the conductive metal-oxide film contacts the semiconductor part at the bottom surface of the first trench.

### Note 9

The device according to any one of notes 1-7, wherein
the conductive metal-oxide film is not located on a bottom surface of the first trench, and
the second electrode contacts the semiconductor part at the bottom surface of the first trench.

### Note 10

The device according to any one of notes 1-9, wherein
the conductive metal-oxide film is located also on an upper surface of the semiconductor part and on an upper surface of the insulating member.

### Note 11

The device according to any one of notes 1-10, wherein
the second electrode includes:
   a first metal layer located inside the first trench, the first metal layer contacting the conductive metal-oxide film; and
   a second metal layer located on the semiconductor part, the second metal layer contacting the conductive metal-oxide film, and
a work function of the first metal layer is greater than a work function of the second metal layer.

### Note 12

The device according to any one of notes 1-11, wherein
the semiconductor part includes:
   a first layer contacting the first electrode;
   a second layer located on the first layer, an impurity concentration of the second layer being less than an impurity concentration of the first layer; and
   a third layer located on the second layer, the third layer contacting the second electrode, an impurity concentration of the third layer being greater than an impurity concentration of the second layer, and
a portion of a first part of the second layer located between the first trench and the second trench contacts the second electrode.

### Note 13

The device according to note 12, wherein
the second layer includes a plurality of the first parts,
an upper surface of every other first part among the plurality of first parts arranged along a first direction contacts the second electrode, and
the first trench and the second trench are arranged along the first direction.

### Note 14

The device according to note 12, wherein
a contact surface between the first part and the second electrode is discontinuously arranged along a second direction, and
the first trench and the second trench extend in the second direction.

### Note 15

The device according to note 12, wherein
a contact surface between the first part and the second electrode is a portion of the side surface of the first trench.

Note 16

The device according to any one of notes 1-15, wherein
a portion of a first part of the semiconductor part located between the first trench and the second trench has a Schottky junction with the second electrode.

What is claimed is:

1. A semiconductor device, comprising:
a first electrode;
a semiconductor part located on the first electrode, the semiconductor part being of a first conductivity type, a first trench and a second trench being formed in an upper surface of the semiconductor part, the first trench and the second trench being separated from each other;
a conductive metal-oxide film located on at least a side surface of the first trench, the conductive metal-oxide film contacting the semiconductor part;
a second electrode located inside the first trench and on the semiconductor part, the second electrode contacting the conductive metal-oxide film and including a metal;
an insulating member located inside the second trench; and
a third electrode located inside the insulating member.

2. The device according to claim 1, wherein
a resistivity of the conductive metal-oxide film is not more than 1 kΩ·cm.

3. The device according to claim 1, wherein
the conductive metal-oxide film includes at least one metal oxide selected from the group consisting of titanium oxide, zinc oxide, magnesium oxide, and aluminum oxide.

4. The device according to claim 3, wherein
the conductive metal-oxide film includes titanium oxide.

5. The device according to claim 1, wherein
a thickness of the conductive metal-oxide film is not more than 20 nm.

6. The device according to claim 1, wherein
a work function of a part of the second electrode contacting at least the conductive metal-oxide film is not less than 4.7 eV.

7. The device according to claim 1, wherein
a part of the second electrode contacting at least the conductive metal-oxide film includes at least one type of material selected from the group consisting of platinum, iridium, nickel, cobalt, tungsten, vanadium nitride, molybdenum nitride, and titanium nitride.

8. The device according to claim 1, wherein
the conductive metal-oxide film is located also on a bottom surface of the first trench, and
the conductive metal-oxide film contacts the semiconductor part at the bottom surface of the first trench.

9. The device according to claim 1, wherein
the conductive metal-oxide film is not located on a bottom surface of the first trench, and
the second electrode contacts the semiconductor part at the bottom surface of the first trench.

10. The device according to claim 1, wherein
the conductive metal-oxide film is located also on an upper surface of the semiconductor part and on an upper surface of the insulating member.

11. The device according to claim 1, wherein
the second electrode includes:
a first metal layer located inside the first trench, the first metal layer contacting the conductive metal-oxide film; and
a second metal layer located on the semiconductor part, the second metal layer contacting the conductive metal-oxide film, and
a work function of the first metal layer is greater than a work function of the second metal layer.

12. The device according to claim 1, wherein
the semiconductor part includes:
a first layer contacting the first electrode;
a second layer located on the first layer, an impurity concentration of the second layer being less than an impurity concentration of the first layer; and
a third layer located on the second layer, the third layer contacting the second electrode, an impurity concentration of the third layer being greater than an impurity concentration of the second layer, and
a portion of a first part of the second layer located between the first trench and the second trench contacts the second electrode.

13. The device according to claim 12, wherein
the second layer includes a plurality of the first parts,
an upper surface of every other first part among the plurality of first parts arranged along a first direction contacts the second electrode, and
the first trench and the second trench are arranged along the first direction.

14. The device according to claim 12, wherein
a contact surface between the first part and the second electrode is discontinuously arranged along a second direction, and
the first trench and the second trench extend in the second direction.

15. The device according to claim 12, wherein
a contact surface between the first part and the second electrode is a portion of the side surface of the first trench.

16. The device according to claim 1, wherein
a portion of a first part of the semiconductor part located between the first trench and the second trench has a Schottky junction with the second electrode.
